(19) United States
(12) Patent Application Publication
(10) Pub. No.: US 2008/0116790 A1
(43) Pub. Date: May 22, 2008

(54) ORGANIC LIGHT EMITTING DIODE DISPLAY DEVICE AND METHOD OF FABRICATING THE SAME

(76) Inventors: Sam-Il Kho, Suwon-si (KR); Byeong-Wook Yoo, Suwon-si (KR); Yeun-Joo Sung, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/943,484

(22) Filed: Nov. 20, 2007

(30) Foreign Application Priority Data
Nov. 22, 2006 (KR) 10-2006-0015944

(51) Int. Cl. H01L 27/32; H01L 51/56

(52) U.S. Cl. 313/504; 445/24

(57) ABSTRACT

Provided are an organic light emitting diode display device including an emission layer structure between a first electrode and a second electrode, in which a first emission layer and a second emission layer are stacked, wherein the first emission layer emits one of red, green and blue light, and the second emission layer comprises a host and dopants of two different colors other than the color of the light emitted from the first emission layer among the red, green, and blue light, capable of reducing a driving voltage and obtaining high emission intensity at each wavelength of red, green, and blue light to thereby efficiently implement full color.

### CROSS-REFERENCE TO RELATED APPLICATION

This application claims priority to and the benefit of Korean Patent Application No. 10-2006-0115944, filed Nov. 22, 2006, the disclosure of which is incorporated herein by reference in its entirety.

### BACKGROUND

1. Technical Field

The present disclosure relates to an organic light emitting diode, and more particularly, to an organic light emitting diode display device including an emission layer, in which dopants having two different colors are included in a host.

2. Description of the Related Art

Generally, an organic light emitting diode display device includes a substrate, an anode disposed on the substrate, an emission layer disposed on the anode, and a cathode disposed on the emission layer. In the organic light emitting diode display device, when a voltage is applied between the anode and the cathode, a hole and an electron are injected into the emission layer. Then, the hole and the electron recombine in the emission layer to create an exciton, which emits light when transitioning from an excited state to a ground state.

In the organic light emitting diode display device, a plurality of emission layers, one each of which emits red, green, and blue light, for example, may be sequentially stacked to thereby produce white light. When the red, green, and blue emission layers are sequentially stacked, the number of deposition process steps for forming the emission layer is increased, and interfacial contact characteristics are affected due to the increased number of interfaces in an organic thin film. Therefore, even if an interface has excellent contact characteristics, it is inevitable that charges diffuse through the interface. As a result, charge mobility may be reduced due to the charge diffusion, and the driving voltage may be increased.

To overcome the problems of the interface in the organic thin film, an emission layer structure with a double layer structure having a two-wavelength emission spectrum of complementary colors, such as blue and orange, has been proposed. Such an emission layer structure permits white-light emission. However, when a full color display device is manufactured using a color filter with this emission layer structure, color gamut may be narrower than in a device including an emission layer structure that has a three-wavelength (red, green, and blue) emission spectrum, and thus the manufacture of full color display device is not easy.

### SUMMARY OF THE INVENTION

Some embodiments disclosed herein provide an organic light emitting diode display device including an emission layer structure capable of reducing a driving voltage when the device is driven, and suitable for a full-color display device.

Some embodiments provide an organic light emitting diode display device, comprising: a substrate; a first electrode disposed over the substrate; a second electrode disposed over the first electrode; and an emission layer structure disposed between the first electrode and the second electrode, wherein, the emission layer structure comprises a stack of a first emission layer and a second emission layer, the first emission layer emits one of red, green and blue light, and the second emission layer comprises a host and dopants for the other two of red, green, and blue light.

In some embodiments, the host of the second emission layer comprises a single material. In some embodiments, the dopants of the second emission layer comprise fluorescent dopants. In some embodiments, the dopants of the second emission layer comprise phosphorescent dopants.

In some embodiments, the first emission layer comprises a host and a dopant. In some embodiments, the first emission layer is a blue emission layer.

In some embodiments, the second emission layer comprises a green dopant and a red dopant.

In some embodiments, the first electrode is an anode, the first emission layer is disposed on the anode, and the second emission layer is disposed on the first emission layer.

In some embodiments, the first emission layer is a blue emission layer, and the second emission layer comprises a green dopant and a red dopant.

In some embodiments, the second emission layer comprises a host selected from the group consisting of CBP, Balq, BCP, and DCB. In some embodiments, a concentration of the green dopant is higher than a concentration of the red dopant. In some embodiments, the green dopant has a concentration of from about 5 wt % to about 10 wt %, and the red dopant has a concentration of from about 0.1 wt % to about 3 wt %.

Some embodiments further comprise at least one of a color filter disposed below the first electrode and a color filter disposed above the second electrode.

In some embodiments, at least one of the first electrode and the second electrode comprises a transparent electrode material. In some embodiments, the transparent electrode material is stacked on a reflective layer.

Some embodiments provide a method for fabricating an organic light emitting diode display device, comprising: providing a substrate; forming a first electrode on the substrate; forming an emission layer structure over the first substrate, wherein forming the emission layer structure comprises: forming a first emission layer emitting one of red, green, and blue light, and forming a second emission layer comprising a host and dopants of the other two of red, green, and blue light; and forming a second electrode over the emission layer structure.

In some embodiments, forming the first emission layer comprises co-depositing a host and a dopant for one of red, green, and blue light. In some embodiments, forming the second emission layer comprises co-depositing the host and the dopants of the other two of red, green, and blue light. In some embodiments, forming the first emission layer and forming the second emission layer comprises vacuum-depositing the first emission layer and second emission layer.

Some embodiments further comprise at least one of forming a color filter below the first electrode and forming a color filter above the second electrode by laser induced thermal imaging.

### BRIEF DESCRIPTION OF THE DRAWINGS

The above and other features will be described in reference to certain exemplary embodiments with reference to the attached drawings in which:

FIG. 1 is a cross-sectional view of an organic light emitting diode display device including an emission layer structure according to a first embodiment;

FIG. 2 is a cross-sectional view of a full color organic light emitting diode display device according to a second embodiment; and

FIG. 3 is a cross-sectional view illustrating emission spectrum characteristics of an organic light emitting diode display device including an emission layer structure according to Example and Comparative Example.

### DETAILED DESCRIPTION OF CERTAIN EMBODIMENTS

Certain embodiments will now be described more fully hereinafter with reference to the accompanying drawings. In the drawings, the thicknesses of layers and regions are exaggerated for clarity. Like reference numerals are used to denote like elements.

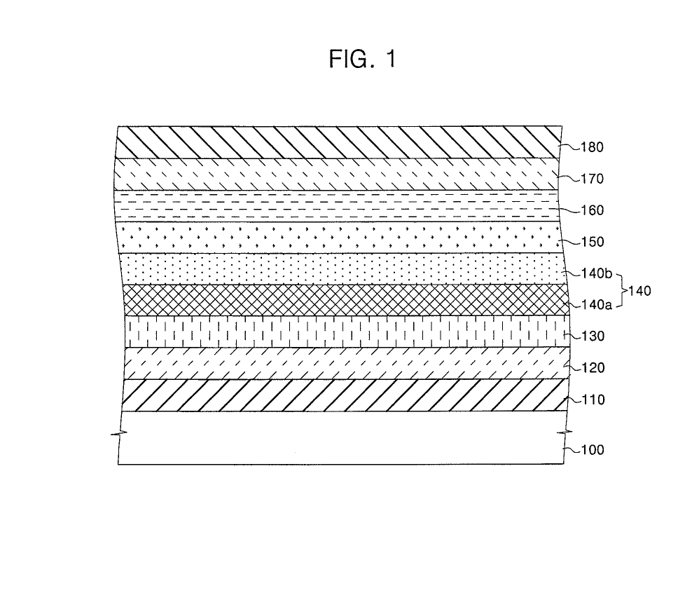

FIG. 1 is a cross-sectional view of an organic light emitting diode display device including an emission layer structure according to a first embodiment. Referring to FIG. 1, a first electrode 110 is formed on a substrate 100. The first electrode 110 may be formed of a transparent electrode or a reflective electrode. When the first electrode 110 is a transparent electrode, it may be formed of indium tin oxide (ITO) or indium zinc oxide (IZO). Meanwhile, when the first electrode 110 is a reflective electrode, it may be formed as a structure in which a transparent electrode material is stacked on a reflective layer. The reflective layer may be formed of silver (Ag), aluminum (Al), chromium (Cr), molybdenum (Mo), tungsten (W), titanium (Ti), thallium (Ta) or an alloy thereof. The transparent electrode material may include ITO or IZO. As a result, the first electrode 110 may be formed as an anode.

A hole injection layer (HIL) 120 as a charge injection layer and a hole transport layer (HTL) 130 as a charge transport layer may be sequentially formed on the first electrode 110. Formation of the hole injection layer 120 or the hole transport layer 130 may be omitted. The hole injection layer 120 is a layer for facilitating injection of a hole into an emission layer to be formed in a following step, and may be formed of a low molecular weight material such as CuPc, TNATA, TCTA, TDAPB, TDATA, etc. or a polymer such as PANI, PEDOT, etc. Also, the hole transport layer 130 is a layer for facilitating transport of a hole into an emission layer to be formed in a following step, and may be formed of a low molecular weight material such as α-NPB, TPD, s-TAD, MTDATA, etc. or a polymer such as PVK.

A first emission layer 140a emitting one of red, green, and blue light is formed on the hole transport layer 130. The first emission layer 140a may be a blue emission layer, as will now be described in greater detail. Since a green dopant has a similar excitation energy level to a red dopant, even if the same host is used, red and green dopants have a low probability of producing an unbalanced emission of light. However, since a blue dopant has an energy level relatively different from a green or red dopant, combinations including blue dopants have a high probability of producing an unbalanced emission of light, depending on a host. Therefore, the first emission layer 140a is formed of only a blue light emitting material in some preferred embodiments. Also, a blue emission layer having a wide energy band gap may be disposed closer to an anode electrode 110 than emission layers of other colors for facilitating the movement of charge.

In this case, the blue emission layer 140a may be formed of a material that can emit light by itself without using a dopant, or formed using a host and a dopant. Generally, using both a host and a dopant yields higher luminous efficiency, and thus the host and the dopant may be co-deposited in forming the layer 140a. Here, any suitable materials known in the art may be appropriately used as the host and the dopant of the blue emission layer 140a. For example, distyrylarylene (DSA), distyrylarylene derivatives, distyrylbenzene (DSB), distyrylbenzene derivatives, BAIq, etc. may be used as the host, and 4,4′-bis(2,2′-diphenylvinyl)-1,1′-biphenyl (DPVBi), distyrylamine (derivatives, pyrene derivatives, perylene derivatives, distyrylbiphenyl (DSBP) derivatives, etc. may be used as the dopant.

A second emission layer 140b including a host and dopants for two colors selected from red, green, and blue, different from the color of the light emitted from the first emission layer 140a is formed on the first emission layer 140a. The second emission layer 140b may be formed by simultaneously co-depositing the dopants of two different colors contemporaneously with the host. The second emission layer 140b may be a layer in which the host is doped with red and green dopants when the first emission layer 140a is a blue emission layer, as discussed above. As described above, the green dopant has a similar energy level to the red dopant, and thus there is a low probability of producing unbalanced emission of light even though the same host is used. Therefore, the red and green dopants may be doped into the same host to form the second emission layer 140b.

Also, both the two dopants of the second emission layer 140b may be a fluorescent dopant or a phosphorescent dopant. Generally, a fluorescent material may have an energy level different from a phosphorescent material. In the second emission layer 140b, the same host is used with two different dopants, and when one of the two dopants comprises a fluorescent material and the other of the dopants comprises a phosphorescent material, smooth energy movement to any dopant is inhibited due to different energy levels of the two dopants. Accordingly, when the red and green dopants are doped together in the second emission layer, and the green dopant comprises a fluorescent dopant, the red dopant also comprises a fluorescent dopant in some embodiments. Also, when the green dopant comprises a phosphorescent dopant, the red dopant also comprises a phosphorescent dopant in some embodiments.

Meanwhile, when the green and red dopants are simultaneously doped into the second emission layer 140b, the concentration of the green dopant may be higher than that of the red dopant. Since energy is transferred from the green dopant to the red dopant, when the concentration of the green dopant is less than or equal to that of the red dopant, most or all of the energy is transferred to the red dopant, so that the greed dopant may not emit any light at all. Therefore, in order to provide both the green and red light, the concentration of the green dopant may be higher than that of the red dopant. Specifically, the concentration of the green dopant in the second emission layer 140b may be from about 5 wt % to about 10 wt %, and the concentration of the red dopant in the second emission layer 140b may be from about 0.1 wt % to about 3 wt %. When the concentration of the green dopant is from about 5 wt % to about 10 wt % and the concentration of the red dopant is less than about 0.1 wt %, it is difficult to generate red light because the emission intensity of red is close to about zero (0) under these conditions. In addition, when the concentration of the red dopant is more than about 3 wt %, it is difficult to generate green light because the emission intensity of green is close to about zero (0) under these conditions.

When the second emission layer comprises green and red emission layers, the host and dopant of the emission layer 140b may be adequately formed of suitable materials known in the art. Materials suitable as a common host for the green and red dopants include 4,4-N,N-dicarbazole-biphenyl (CBP), BAlq, BCP, DCB, etc. Suitable green dopants include 10-(1,3-benzothiazole-2-yl)-1,1,7,7-tetramethyl-2,3,6,7-tetrahydro-1H,5H,11H-pyrano(2,3-f)pyrido(3,2,1-ij)quinoline-11-one (C545T), quinacridone derivatives, tris-(2-phenylpyridine)iridium(Ir(PPy)₃), etc. Suitable red dopants include PQIr, Btp₂Ir(acac), 4-(dicyanomethylene)-2-t-butyl-6-(1,1,7,7-tetramethyljulolidyl-9-enyl)-4H-pyran (DCJTB), 4-(dicyanomethylene)-2-methyl-6-(p-dimethylaminostyryl)-4H-pyran (DCM), 2,3,7,8,12,13,17,18-octaethyl-21H,23H-porphyrin-platinum (II)(PtOEP), Ir(piq)₂(acac), rubrene, etc.

The first emission layer 140a and the second emission layer 140b together form an emission layer structure 140.

Subsequently, a hole blocking layer (HBL) 150 may be formed on the second emission layer 140b. The hole blocking layer 150 serves to prevent diffusion of excitons generated in the second emission layer 140b in the process of driving an organic light emitting diode. The hole blocking layer 150 may be formed of Balq, BCP, CF-X, TAZ or spiro-TAZ.

An electron transport layer (ETL) 160 as a charge transport layer and an electron injection layer (EIL) 170 as a charge injection layer may be sequentially formed on the hole blocking layer 150. The electron transport layer 160 facilitates transport of electrons to the emission layers 140a and 140b, and may be formed of a material such as TAZ, PBD, spiro-PBD, Alq₃, BAlq, or SAlq. The electron injection layer 170 is a layer that facilitates injection of electrons into the emission layers 140a and 140b, and may be formed of a material such as Alq₃, LiF, a Ga complex, or PBD.

Then, a second electrode 180 is formed on the electron injection layer 170. The second electrode 180 may be formed of magnesium (Mg), calcium (Ca), aluminum (Al), silver (Ag), barium (Ba), or alloys thereof. When the second electrode 180 is a transparent electrode, it is formed thin enough for light to pass through, and when the second electrode 180 is a reflective electrode, it is formed thicker. As a result, the second electrode 180 may be formed as a cathode. At least one of the first electrode 110 and the second electrode 180 are formed of a transparent electrode through which light can pass.

As an alternative embodiment, the first electrode 110 may be formed as a cathode, and the second electrode 180 may be formed as an anode. In this case, an organic light emitting diode display device may be formed with a structure, in which the first electrode 110, the electron injection layer 170, the electron transport layer 160, the hole blocking layer 150, the second emission layer 140b, the first emission layer 140a, the hole transport layer 130, the hole injection layer 120, and the second electrode 180 are sequentially stacked on the substrate 100.

In some embodiments, the first emission layer 140a may be disposed on the second emission layer 140b, where the first emission layer 140a may be formed to emit green or red light, and in the second emission layer 140b, a host is doped with red and blue dopants or green and blue dopants, respectively.

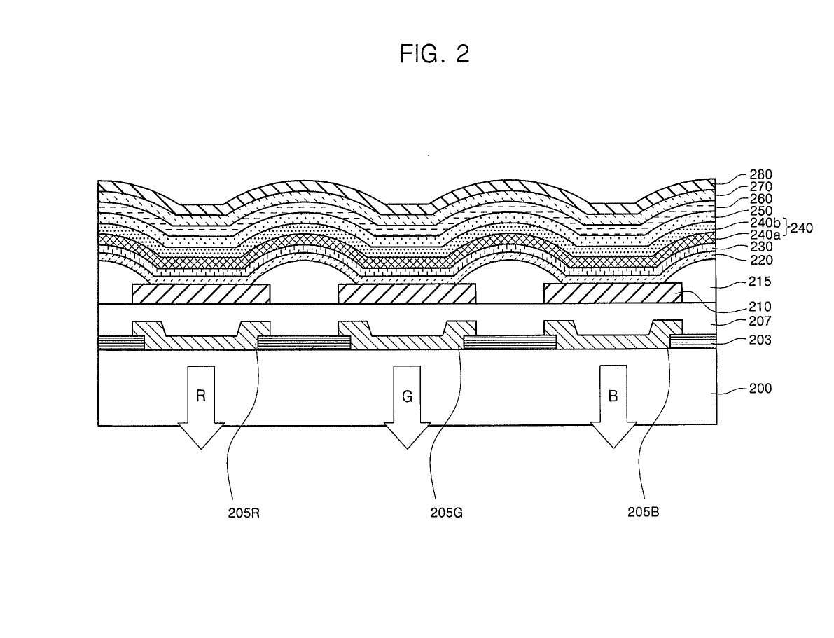

FIG. 2 is a cross-sectional view of a full-color organic light emitting diode display device according to a second embodiment. Referring to FIG. 2, a substrate 200 is provided. The substrate 200 may be formed of a transparent material through which light can pass. Black matrixes 203 spaced apart from each other are formed on the substrate 200. The black matrixes 203 serve to absorb external light and scattered light. A red color filter layer 205R, a green color filter layer 205G, and a blue color filter layer 205B may be respectively formed between the black matrixes 203. In this case, the color filter layers may be formed by a laser induced thermal imaging method.

Each of the filter layers may include a pigment and a polymer binder. The red color filter layer 205R, the green color filter layer 205G, and the blue color filter layer 205B, respectively, transmit red wavelengths, green wavelengths, and blue wavelengths of light emitted from an emission layer formed in the following steps. For this purpose, the red color filter layer 205R, the green color filter layer 205G, and the blue color filter layer 205B include pigments having characteristics different from each other.

Subsequently, an overcoating layer 207 may be formed on the substrate where the red, green, and blue filter layers 205R, 205G, and 205B are formed. The transparent overcoating layer 207 protects the color filter layers 205R, 205G, and 205B from physical damage, etc., and reduces a step height caused by the formation of the color filter layers 205R, 205G, and 205B. First electrodes 210 are formed on the overcoating layer 207, which correspond to the color filter layers 205R, 205G, and 205B, respectively. The first electrodes 210 may be a transparent electrode.

A pixel definition layer 215 having an opening that partially exposes surfaces of the first electrodes 210 may be formed over the substrate 200 and the first electrodes 210. The pixel definition layer 215 may be formed of any suitable material, for example, an acrylic organic layer. Then, a first emission layer 240a and a second emission layer 240b are sequentially formed over the entire surface of the substrate 200 including the exposed first electrodes 210. The first emission layer 240a and the second emission layer 240b together form an emission layer structure 240. A hole injection layer 220 or a hole transport layer 230 may be further formed over the exposed first electrode 210 before the formation of the first emission layer 240a. In addition, a hole blocking layer 250 may be formed on the second emission layer 240b. An electron transport layer 260 or/and an electron injection layer 270 may be formed on the hole blocking layer 250. A second electrode 280 crossing the first electrodes 210 is formed on the electron injection layer 270.

Detailed descriptions of the first electrode 210, the hole injection layer 220, the hole transport layer 230, the first emission layer 240a, the second emission layer 240b, the hole blocking layer 250, the electron transport layer 260, the electron injection layer 270, and the second electrode 280 are made with reference to the first embodiment.

When the organic light emitting display device is driven, the emission layer structure 240 emits white light. The white light emitted from the emission layer structure 240 is transmitted out of the device through the transparent first electrode 210 and the transparent substrate 200. Here, the color filter layers 205R, 205G, and 205B are disposed on paths through which the light emitted from the emission layer structure 240 passes. As a result, the white light emitted from the emission layer structure 240 passes through the respective red, green, and blue color filter layers 205R, 205G, and 205B, and out of the device, so that full color may be implemented using red, green, and blue colors when the organic light emitting diode display device is driven.

In the present embodiment, an organic light emitting diode display device in which the color filter layer is disposed below the emission layer structure 240, i.e., a bottom-emission organic light emitting diode display device, is exemplified. However, one of ordinary skill in the art would understand that other embodiments provide a top-emission organic light emitting diode display device or a dual-emission organic light emitting diode display device as well.

The example describes a particular embodiment to which the disclosure should not be construed to be limited.

### EXAMPLE

### Fabrication of an Organic Light Emitting Diode Display Device Including a White Emission Layer Structure with a Double Layer Structure

A 2 mm×2 mm ITO first electrode was formed on a substrate, followed by ultrasonic cleaning and pre-treatment (UV-O3 treatment, and annealing treatment). A 750

A thick layer of IDE406 (Idemitsu Co. Ltd.) was vacuum-deposited on the pre-treated first electrode, thereby forming a hole injection layer. A 150 Å thick layer of IDE320 (Idemitsu Co. Ltd.) was vacuum-deposited on the hole injection layer, thereby forming a hole transport layer. 5 wt % of BD052 (Idemitsu Co. Ltd.) was doped into BH215 (Idemitsu Co. Ltd.), and an 80 Å thick layer was vacuum-deposited on the hole transport layer, thereby forming a first emission layer that emits blue light. TMM004 (Merck & Co.) was doped with 7 wt % Ir(PPy)₃ and 1 wt % TER021 (Merck & Co.), and a 220 Å thick layer was vacuum-deposited on the first emission layer, thereby forming a second emission layer with green and red dopants doped into the same host. On the second emission layer, a 50 Å thick layer of BAlq was vacuum-deposited, a 300 Å thick layer of Alq3 was vacuum-deposited, and a 5 Å thick layer of LiQ was vacuum-deposited, thereby sequentially forming a hole blocking layer, an electron transport layer, and an electron injection layer. A 2000 Å thick layer of Al was vacuum-deposited on the electron injection layer, thereby forming a second electrode.

### COMPARATIVE EXAMPLE

### Fabrication of an Organic Light Emitting Diode Display Device Including a White Emission Layer Structure with a Triple Layer Structure

A 2 mm×2 mm ITO first electrode having an area of was formed on a substrate, followed by ultrasonic cleaning and pre-treatment (UV-03 treatment, and annealing treatment). A 750 Å thick layer of IDE406 (Idemitsu Co. Ltd.) was vacuum-deposited on the pre-treated first electrode, thereby forming a hole injection layer. A 150 Å thick layer of IDE320 (Idemitsu Co. Ltd.) was vacuum-deposited on the hole injection layer, thereby forming a hole transport layer. 5 wt % of BD052 (Idemitsu Co. Ltd.) was doped into BH215 (Idemitsu Co. Ltd.), and an 80 Å thick layer was vacuum-deposited on the hole transport layer, thereby forming a first emission layer that emits blue light. TMM004 (Merck & Co.) was doped with 7 wt % Ir(PPy)₃, and a 100 Å thick layer was vacuum-deposited on the first emission layer, thereby forming a second emission layer that emits green light. TMM004 (Merck & Co.) was doped with 15 wt % TER021 (Merck & Co.), and a 120 Å thick layer was vacuum-deposited on the second emission layer, thereby forming a third emission layer that emits red light. On the third emission layer, a 50 Å thick layer of BAlq was vacuum-deposited, a 300 Å thick layer of Alq3 was vacuum-deposited, and a 5 Å thick layer of LiQ was vacuum-deposited, thereby sequentially forming a hole blocking layer, an electron transport layer, and an electron injection layer. A 2000 Å thick layer of Al was vacuum-deposited on the electron injection layer, thereby forming a second electrode.

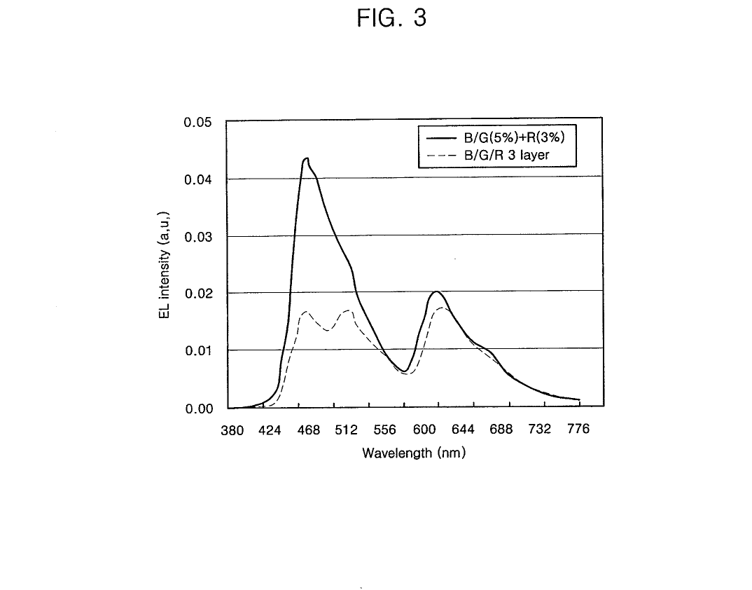

TABLE 1 provides driving voltages and luminous efficiencies at a brightness of 1000 nit of the organic light emitting diode display devices including emission layer structures fabricated according to the Example and the Comparative Example. Emission spectra are shown in FIG. 3.

TABLE 1

| | Driving | Luminous |
|---|---|---|
| | Voltage (V) | Efficiency (Cd/A) |
| Example | 5.39 | 5.80 |
| Comparative Example | 6.67 | 5.95 |

Referring to TABLE 1, while luminous efficiency of the organic light emitting diode display device including a white emission layer structure of the Example was reduced by 2.5% compared with the Comparative Example, this difference is not generally regarded as significant. However, the driving voltage of the Example was significantly reduced by 19.2% compared with the Comparative Example. Also, referring to FIG. 3, the emission intensity in the Example at each wavelength of red, green, and blue light was higher than that of the Comparative Example. Therefore, embodiments of an organic light emitting diode display device including a white emission layer structure with a double layer structure, in which a first emission layer includes one of red, green, and blue dopants and a second emission layer includes dopants of the remaining two colors, driving voltage characteristics are considerably improved, and emission intensity at each wavelength of red, green, and blue light is also improved as compared with an organic light emitting diode display device including a white emission layer structure with a triple layer structure, in which red, green, and blue emission layers are sequentially stacked. Accordingly, when the present organic light emitting diode display device is used in full-color organic light emitting diode display devices employing a color filter layer, full-color characteristics are improved.

As described above, in an organic light emitting diode display device including a white emission layer structure with a double layer structure, in which a first emission layer includes one of red, green, and blue dopants, and a second emission layer includes dopants of the remaining two colors, driving voltage is reduced, one deposition process is also eliminated, and high emission intensity at each wavelength of red, green, and blue light can be obtained. As a result, when a color filter is applied, the full-color may be efficiently implemented.

Although the certain exemplary embodiments have been described, it will be understood by those skilled in the art that a variety of modifications and variations may be made without departing from the spirit or scope of the disclosure, which is defined in the appended claims, and their equivalents.

What is claimed is:

1. An organic light emitting diode display device, comprising:
a substrate;
a first electrode disposed over the substrate;
a second electrode disposed over the first electrode; and
an emission layer structure disposed between the first electrode and the second electrode, wherein,
the emission layer structure comprises a stack of a first emission layer and a second emission layer,
the first emission layer emits one of red, green and blue light, and
the second emission layer comprises a host and dopants for the other two of red, green, and blue light.

2. The device of claim 1, wherein the host of the second emission layer comprises a single material.

3. The device of claim 1, wherein the dopants of the second emission layer comprise fluorescent dopants.

4. The device of claim 1, wherein the dopants of the second emission layer comprise phosphorescent dopants.

5. The device of claim 1, wherein the first emission layer comprises a host and a dopant.

6. The device of claim 1, wherein the first emission layer is a blue emission layer.

7. The device of claim 1, wherein the second emission layer comprises a green dopant and a red dopant.

8. The device of claim 1, wherein the first electrode is an anode, the first emission layer is disposed on the anode, and the second emission layer is disposed on the first emission layer.

9. The device of claim 8, wherein the first emission layer is a blue emission layer, and the second emission layer comprises a green dopant and a red dopant.

10. The device of claim 7, wherein the second emission layer comprises a host selected from the group consisting of CBP, Balq, BCP, and DCB.

11. The device of claim 7, wherein a concentration of the green dopant is higher than a concentration of the red dopant.

12. The device of claim 7, wherein the green dopant has a concentration of from about 5 wt % to about 10 wt %, and the red dopant has a concentration of from about 0.1 wt % to about 3 wt %.

13. The device of claim 1, further comprising at least one of a color filter disposed below the first electrode and a color filter disposed above the second electrode.

14. The device of claim 1, wherein at least one of the first electrode and the second electrode comprises a transparent electrode material.

15. The device of claim 14, wherein the transparent electrode material is stacked on a reflective layer.

16. A method for fabricating an organic light emitting diode display device, comprising:
providing a substrate;
forming a first electrode on the substrate;
forming an emission layer structure over the first substrate, wherein forming the emission layer structure comprises:
forming a first emission layer emitting one of red, green, and blue light, and
forming a second emission layer comprising a host and dopants of the other two of red, green, and blue light; and
forming a second electrode over the emission layer structure.

17. The method of claim 16, wherein forming the first emission layer comprises co-depositing a host and a dopant for one of red, green, and blue light.

18. The method of claim 16, wherein forming the second emission layer comprises co-depositing the host and the dopants of the other two of red, green, and blue light.

19. The method of claim 16, wherein forming the first emission layer and forming the second emission layer comprises vacuum-depositing the first emission layer and second emission layer.

20. The method of claim 16, further comprising at least one of forming a color filter below the first electrode and forming a color filter above the second electrode by laser induced thermal imaging.
